(19) United States
(12) Patent Application Publication
(10) Pub. No.: US 2004/0164750 A1
(43) Pub. Date: Aug. 26, 2004

(54) Digital time domain reflectometry moisture sensor

(75) Inventor: Scott Knudson Anderson, Meridian, ID (US)

Correspondence Address: ROBERT FROHWERK, 551 CLEARVUE DRIVE, MERIDIAN, ID, 83642, US

(73) Assignee: Technical Development Consultants, Inc., Meridian, ID

(21) Appl. No.: 10/367,310

(22) Filed: Feb. 19, 2003

(51) Int. Cl. G01R 27/26

(52) U.S. Cl. 324/664

(57) ABSTRACT

A method and apparatus for detecting volumetric moisture content and conductivity in various media based on the time-domain reflectometry (TDR) system disclosed in patent application Ser. No. 09/945528. As in patent application Ser. No. 09/945528, successive square waves are generated and transmitted on a transmission line through a medium of interest, and a characteristic received waveform is digitized and analyzed by continuously sampling multiple received waveforms at short time intervals. Unlike the former system, the system in this disclosure does not propagate the waveform along a transmission line to a receiver at the other end of the line, but uses a reflected wave approach in which the waveform propagates down a shorted or open ended transmission line and reflects back to a receiver connected to the same end of the line as the transmitter. The effects of dispersion caused by the conductive and dielectric properties of the medium on the waveform sent on the transmission line are extrapolated. This is accomplished by detecting the bulk propagation time and the slope of the distorted rising edge of the characteristic received waveform. Absolute volumetric moisture percentage is inferred from propagation time, and absolute conductivity is inferred from the maximum slope value of the distorted rising edge of the characteristic received waveform.

### CROSS REFERENCE TO RELATED APPLICATIONS

### U.S. PATENT DOCUMENTS

| | | | |
|---|---|---|---|
| 6,215,317 | 04/2001 | Siddiqui, et al. | 324/643 |
| 6,441,622 | 08/2002 | Wrzeninski, et al. | 324/643 |

### U.S. PATENT APPLICATIONS

Anderson, Scott K. “Absolute-Reading Moisture and Conductivity Sensor”. application Ser. No. 09/945528.

### STATEMENT REGARDING FEDERALLY SPONSORED R & D

Not Applicable

### REFERENCE TO A MICROFICHE APPENDIX

Not Applicable

### TECHNICAL FIELD

The present invention relates generally to electronic moisture sensors, and specifically to time domain reflectometry moisture sensors. This invention represents a modification to the method and apparatus for extrapolating soil moisture and conductivity disclosed in patent application Ser. No. 09/945528.

### BACKGROUND OF THE INVENTION

A variety of sensors have been developed to detect moisture in various media. These include conductivity sensors, bulk dielectric constant sensors, time domain reflectometer or transmissometry (TDR or TDT) type sensors, and various oscillator devices, the majority of which exploit the high dielectric constant of water to extrapolate moisture content in the medium. In particular, TDR type sensors have been used over the past several years to measure the water content in various applications. Such applications include detecting volumetric soil moisture, determining liquid levels in tanks, and determining moisture content in paper mills and granaries.

A major setback in determining volumetric moisture content in a medium is the influence of conductive materials in the medium of interest. For example, soil conductivity is a function of the ion content of the soil and of its temperature. Salts from irrigation water and/or fertilizer can build up in the soil and cause significant errors in TDR-based moisture readings.

Because of the uncertainty in moisture readings caused by conductivity, many of the TDR sensors now available are “relative” sensors. This means that the sensor does not report absolute moisture content readings, but uses reference points obtained through testing. In essence, the moisture sensor does not report absolute moisture content readings, but reports a “wetter than” or “drier than” condition based on the relative difference of the conductivity-dependant moisture content reading and the reference reading.

Unfortunately, the readings from these “relative” sensors do not remain in synchronism with the true or “absolute” water content of the medium, but fluctuate with time. For example, the salinity (ionic content) of soil may fluctuate with season. In such a case, the original reference point becomes an inaccurate indicator of the moisture level of the medium.

The method and apparatus disclosed in patent application Ser. No. 09/945528 provide a way to report absolute volumetric water content of a medium. This is done by essentially analyzing the distortion effects on a transmitted waveform caused by the properties (namely conductivity and dielectric constant) of the medium. The method and apparatus disclosed in patent application Ser. No. 09/945528 provide a means to launch a fast rising positive edge on a transmission line passing through a specific length of soil. The transmission line folds back to a receiver mounted on the same circuit board as the transmitter. As a result of housing the transmitting and receiving electronics on the same circuit board, and folding the transmission line, feed-through noise is inherent in the characteristic received waveform.

The disclosed invention is a method and apparatus similar to that disclosed in patent application Ser. No. 09/945528, however, a reflected wave approach is incorporated. The transmitter launches a step function at one end of a transmission line, the other end of which is shorted or open. The fast rising step function propagates down the line and is reflected at the shorted or open end back to the point of origin. A receiver samples and digitizes the returning waveform into close-spaced digital samples representing the amplitude at precise time intervals of the returned waveform. Analysis of these samples yields an accurate measurement of the round-trip propagation time of the step function—even in the presence of waveform distortion caused by conductive elements in the medium surrounding the transmission line. From the propagation time the bulk dielectric constant of the medium can be determined and from that the volumetric moisture content of the medium. Further analysis of the distortion of the waveform yields the bulk electrical conductivity of the medium.

### SUMMARY OF THE INVENTION

The disclosed invention is a method and apparatus for inferring volumetric moisture content and bulk conductivity of a medium of interest using a TDR-based system based on the disclosure in patent application Ser. No. 09/945528. The present invention describes a reflected wave approach to measure the propagation time.

As in patent application Ser. No. 09/945528, a very precise timing and successive approximation amplitude-measuring scheme captures the timing and amplitude of the received waveform with pico-second and milli-volt resolution, respectively. From point-by-point measurements the characteristic received waveform is examined. Propagation delay of the characteristic received waveform is set as the first time when the amplitude of the received waveform is greater than a threshold. The maximum slope of the characteristic received waveform is also examined. This information is used to infer bulk dielectric constant and conductivity, respectively, of the moisture-bearing medium.

### BRIEF DESCRIPTION OF THE DRAWINGS

FIG. 1 is a simplified block diagram of the sensor system with important components labeled.

FIG. 2 shows typical waveforms transmitted and received by the apparatus.

### DETAILED DESCRIPTION OF THE INVENTION

The disclosed apparatus is essentially identical to that disclosed in patent application Ser. No. 09/945528 with modifications introduced to allow the transmitter and receiving units to be connected to the same end of the open or shorted transmission line. The method of extracting propagation delay and maximum slope are slightly different due to the inherent difference in the characteristic received waveform.

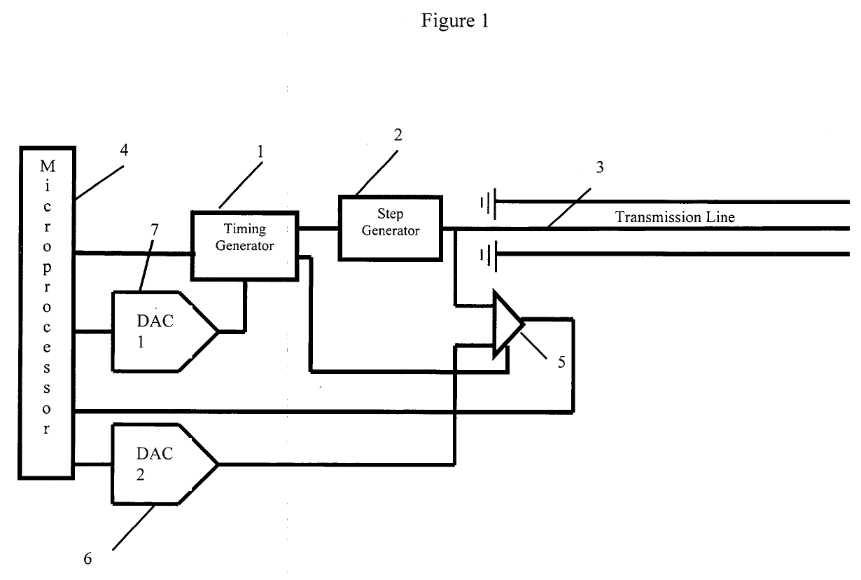

The important elements of the moisture sensor are diagrammed in FIG. 1. This figure is a simplified block diagram of a precisely-timed waveform generator coupled with a successive approximation amplitude measurement system capable of capturing the detail of very fast waveforms. The timing generator (1) provides two trigger signals that are precisely separated in time by a programmable offset ranging from zero to tens of nanoseconds with a resolution of tens of picoseconds. The offset amount is governed by the setting of a digital to analog converter (DAC) (7).

The first trigger activates a step function generator (2). The output of this generator is a very fast rising edge that propagates down the transmission line (3) to the shorted or open end where it reflects and returns to the receiving comparator (5). The second trigger is applied to the latch input of the latching comparator (5). If the waveform amplitude at the driving and receiving end of the transmission line (3) is higher in amplitude than the DAC (6) driving the other input at the at the time of the second trigger, then the comparator (5) provides a logical ‘1’ output. If the incoming waveform is lower than the DAC (6) setting, the comparator (5) provides a logical ‘0’ output. The comparator's captured state is then examined by the microprocessor (4). The microprocessor adjusts DAC (6) and launches successive step functions until the amplitude of the waveform at the time of the second trigger has been acquired. Then the second trigger point can be moved to the next time increment such that the amplitude at that time point can be digitized. By repeatedly measuring the waveform amplitude at successive time increments, the entire waveform can be reconstructed. This reconstructed waveform is referred to hereafter as the characteristic received waveform.

Measuring the amplitude of the characteristic received waveform at a given time point is accomplished through a successive approximation technique requiring a sequence of waveform launch and receive cycles. The number of cycles required is equal to the number of resolution bits in the amplitude DAC (6). First, the trigger spacing is set in the timing DAC (7). This setting represents the time after the launch of the waveform that the received waveform will be sampled. This setting will remain fixed while the amplitude at this point is found. Next, the amplitude DAC (6) is set to half scale (the most significant bit is set and all others are cleared). Then an output from the microprocessor (4) starts the timing generator (1). The first trigger from the timing generator (1) causes the step generator (2) to launch a step on the transmission line (3). At the precisely programmed interval later, the second trigger latches the input to the receiving comparator (5). Next, the microprocessor (4) examines the comparator (5) output. If it is a logical ‘1’ (waveform is higher than amplitude DAC [6]), then the microprocessor leaves the last set bit in its set state and sets the next most significant bit. Then another step function is launched on the transmission line (3). The sequence repeats until all bits in the amplitude DAC (5) have been successively processed from the most significant to the least significant. The resulting amplitude DAC (6) input setting is the digital representation of the waveform amplitude at the precise time that was loaded into the timing DAC (7).

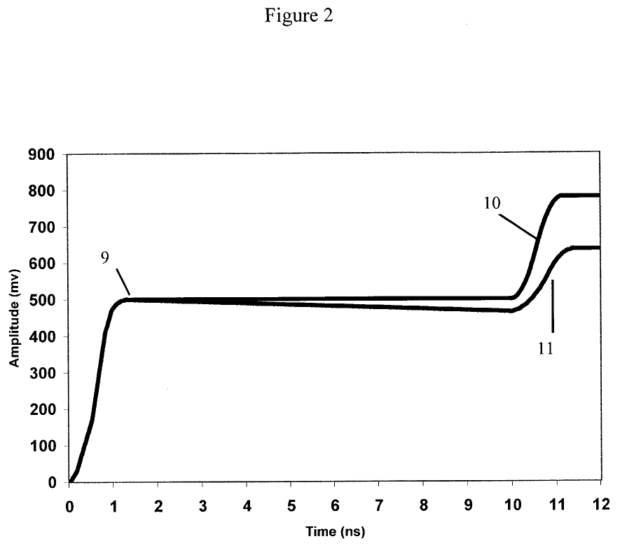

FIG. 2 represents waveform measurements taken at successive time increments using the aforementioned process. Waveform (9) represents the digitized waveform appearing at the driving/receiving end of the transmission line after a step function has been transmitted. The right-hand portion of the waveform (10) represents the portion of the characteristic received waveform that has propagated through moist soil, has reflected off the open distant end of the transmission line and has returned to the point of origin. Note that this waveform segment (10) is a positive rising segment. If the transmission line were shorted it would be a decreasing negative-going segment. Either case applies in this disclosure. The amplitude and slope of segment (10) are affected by the electrical conductivity of the medium in which the transmission is immersed. The timing of the rise of segment (10) is determined by the bulk dielectric constant of the medium. Note that in the apparatus described in patent application Ser. No. 09/945528, a low level signal leads the waveform. This low signal represents residual feed-through due to the fact that the transmitter and receiver were housed on the same circuit board. In the present disclosure, the lead portion of the received waveform is identical with the transmitted waveform since the receiver is connected across the transmitter output terminals Waveform (11) represents the characteristic received waveform that has propagated through moist soil that has higher conductivity than the waveform for the medium associated with waveform (10). Note that waveform (11) differs from waveform (10) in that the rising edge slope is not as steep. However, the propagation times are nearly identical. This is expected since waveforms (10) and (11) represent characteristic received waveforms that have propagated through soils of equal wetness, but different conductivities.

For a given characteristic received waveform, the bulk dielectric constant and the conductivity of the medium of interest may be determined through the following steps. First, the point of maximum slope of the reflected portion of the waveform is found from a mathematical analysis of the digitized waveform samples. This is done as in patent application Ser. No. 09/945528 by taking the derivative of a moving average of successive samples and locating the point of the maximum derivative. The timing, slope and amplitude of that point are retained. Next, the approximate point of upward inflection of segment (10) is determined through a search for the maximum 2nd derivative of successive digitized waveform samples. Once that point is found a search is made for a zero-slope waveform segment just to the left of the inflection point. The amplitude at that point represents the baseline amplitude above which the reflected wave rises. The earlier-calculated maximum slope is projected from its amplitude and timing coordinates down to this baseline. The intersection of the slope with the baseline represents the propagation time. The slope of segment (10) can also be used to infer the conductivity of the medium.

This method is advantageous since the maximum slope point is the place in the received waveform where most of the energy of the transmitted energy is returning to the receiver, hence at this point there is the greatest signal to noise ratio, assuming stationary noise statistics. The slope amplitude (V/s) and temporal position (s) are accurate and repeatable.

The maximum slope of the characteristic received waveform is located in the following manner. Since we expect that the characteristic received waveform will contain noise, a smoothing first derivative approximation is incorporated. To approximate the derivative at each point, a thirty-two point window of data is stored. The first derivative approximation at a point in the center of the window is calculated as the sum of the second sixteen entries minus the first sixteen entries, divided by the sum of the thirty-two entries.

A search for the maximum slope begins at a time when the characteristic received waveform is greater than some voltage above the waveform. The maximum slope, its temporal location, and the amplitude at that location are stored. Propagation time is then determined by projecting a the maximum slope line onto the baseline.

What I claim is:

1. An apparatus for digitizing a waveform sent along a transmission line from a transmitter through a moisture-bearing medium and back to a receiver comprising the steps of:
A) providing a step-function or pulse generator;
B) providing a transmission line that passes through the medium to an open or shorted distal end;
C) providing a latching comparator to receive the reflected signal arriving back at the generator end of the transmission line;
D) launching a step function or pulse waveform on the transmission line;
E) sending a latch signal to the latching comparator;
F) measuring the amplitude of the waveform at a programmed time point at the latching comparator by using a timing and successive approximation amplitude-measuring technique comprising the steps of:
a) providing a programmable voltage reference to which the waveform is compared by the latching comparator;
b) providing a programmable time offset to set a precisely-timed sampling strobe after the launch of the waveform to sample the waveform amplitude at the latching comparator;
c) launching multiple, identical step function waveforms and adjusting the programmable voltage reference in a successive approximation fashion until the amplitude of the waveform at the given point has been acquired;
G) changing the programmable time offset to the next desired time point and acquiring the amplitude of the waveform at that point.

2. A method in claim 1, wherein the propagation time of the waveform through the medium of interest is calculated from the digitized received waveform, comprising the steps of:
A) determining the slope of the reflected waveform transition from a set of measured points;
B) locating the point of maximum slope of the reflected waveform transition;
C) determining the baseline from which the reflected waveform transition rises;
D) projecting a straight line through the maximum slope point to the baseline;
E) finding the intercept point of the projected line and the baseline, wherein the timing of the intercept point represents the propagation time of the waveform.

3. The method in claim 2, wherein the propagation time is used to calculate the bulk dielectric constant of the medium in contact with the transmission line.

4. The method in claim 2 wherein the slope information from a returning waveform is used to determine the conductivity of the medium in contact with the transmission line.

5. An apparatus in claim 1, wherein the medium of interest is soil.
